(19) United States
(12) Patent Application Publication
(10) Pub. No.: US 2014/0000673 A1
(43) Pub. Date: Jan. 2, 2014

(54) PHOTOVOLTAIC DEVICE AND METHOD OF MAKING

(71) Applicants: Jinbo Cao, Rexford, NY (US); Bastiaan Arie Korevaar, Schenectady, NY (US); Hongying Peng, Clifton Park, NY (US); Allan Robert Northrup, Schenectady, NY (US)

(72) Inventors: Jinbo Cao, Rexford, NY (US); Bastiaan Arie Korevaar, Schenectady, NY (US); Hongying Peng, Clifton Park, NY (US); Allan Robert Northrup, Schenectady, NY (US)

(73) Assignee: GENERAL ELECTRIC COMPANY, SCHENECTADY, NY (US)

(21) Appl. No.: 13/538,415

(22) Filed: Jun. 29, 2012

(51) Int. Cl. H01L 31/0264; H01L 31/18; H01L 31/0224; H01L 31/042; H01L 31/0296; H01L 31/0272

(52) U.S. Cl. 136/244; 136/252; 136/265; 136/260; 136/264; 136/262; 438/86; 438/85; 257/E31.015

(57) ABSTRACT

A photovoltaic device is presented. The device includes a first semiconductor layer disposed on a second semiconductor layer. The first semiconductor layer includes a compound having a metal species, sulfur, and oxygen. The metal species may include zinc, magnesium, tin, indium, or a combination thereof. Method for making a photovoltaic device is also presented.

### BACKGROUND

The invention relates generally to photovoltaic devices. More particularly, the invention relates to photovoltaic devices that include a layer, and to a method for making the photovoltaic devices including the layer thereof.

Photovoltaic (“PV”) devices or cells convert light directly into electricity. Photovoltaic devices are used in numerous applications, from small energy conversion devices for calculators and watches to large energy conversion devices for households, utilities, and satellites.

The cost of conventional photovoltaic cells or solar cell, and electricity generated by these cells, is generally comparatively high. For example, a typical solar cell achieves a conversion efficiency of less than 20 percent. Cell conversion efficiency typically represents the efficiency of converting sunlight to electrical energy. Thus, one of the main focuses in the field of photovoltaic devices is the improvement of conversion efficiency.

Solar energy is abundant in many parts of the world. Unfortunately, the available solar energy is not generally used efficiently to produce electricity. Photovoltaic devices often suffer reduced performance due to loss of light, through, for example, reflection and absorption. Therefore, research in optical designs of these devices includes light collection and trapping, spectrally matched absorption and up/down light energy conversion.

Absorption of light by a window layer can be one of the phenomena limiting the conversion efficiency of a PV cell. One of the ways to minimize absorption losses is to incorporate a wide bandgap window layer. It is well known in the art that the design and engineering of window layers should have as high a bandgap as possible to minimize absorption losses. The window layer should also be materially compatible with the absorber layer so that the interface between the absorber layer and the window layer contains negligible interface defect states. Typically, cadmium sulfide (CdS) has been used to make the window layer in photovoltaic cells, e.g. solar cells incorporating absorber layers made of cadmium telluride (CdTe) or copper indium gallium diselenide (CIGS). One major drawback for cadmium sulfide is its relatively low bandgap that causes considerable absorption in the short wavelength region, and thus results in current loss in the device. Thus, it is desirable to keep the window layer as thin as possible to help reduce optical losses by absorption. However, for most of the thin-film PV devices, if the window layer is too thin, a loss in performance can be observed due to low open circuit voltage (V_{OC}) and fill factor (FF).

Therefore, there remains a need for an improved solution to the long-standing problem of inefficient and complicated solar energy conversion devices and methods of manufacture.

### BRIEF DESCRIPTION OF THE INVENTION

Embodiments of the invention are directed towards a window layer for a photovoltaic device and a method for depositing the same.

In one embodiment, a photovoltaic device includes a first semiconductor layer disposed on a second semiconductor layer. The first semiconductor layer includes a compound having a metal species, sulfur, and oxygen. The metal species includes zinc, magnesium, tin, indium, or a combination thereof. A photovoltaic module including a plurality of such photovoltaic devices is also presented.

One embodiment is a photovoltaic device including a first semiconductor layer, a second semiconductor layer disposed on the first semiconductor layer, and a third semiconductor layer disposed on the second semiconductor layer. The first semiconductor layer includes a compound having a metal species, sulfur and oxygen. The metal species includes zinc, magnesium, tin, indium, or a combination thereof. The second semiconductor layer includes cadmium sulfide, and the third semiconductor layer includes cadmium telluride.

One embodiment is a method. The method includes disposing a second semiconductor layer between a first semiconductor layer and a third semiconductor layer. The first semiconductor layer includes a compound having a metal species, sulfur, and oxygen. The metal species includes zinc, magnesium, tin, indium, or a combination thereof. In one embodiment, the method includes the steps of depositing the first semiconductor layer on a substrate, depositing the second semiconductor layer on the first semiconductor layer followed by depositing the third semiconductor layer on the second semiconductor layer.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic of a photovoltaic device, in accordance with one embodiment of the invention;

FIG. 2 is a schematic of a photovoltaic device, in accordance with one embodiment of the invention;

FIG. 3 shows XPS depth profiles of a first semiconductor layer before and after thermal processing, in accordance with one embodiment of the invention;

FIG. 4 shows optical transmission of a zinc sulfide layer with varying oxygen concentration;

FIG. 5 shows the performance parameters for photovoltaic devices, in accordance with some embodiments of the invention.

### DETAILED DESCRIPTION

As discussed in detail below, some of the embodiments of the invention include photovoltaic devices with a semiconductor layer including a compound having a metal species, sulfur, and oxygen. Further, some of the embodiments of the invention include photovoltaic devices including a first semiconductor layer, a second semiconductor layer (for example, n-type CdS) disposed on the first semiconductor layer, and a third semiconductor layer (for example, p-type CdTe) disposed on the second semiconductor layer. The first semiconductor layer includes a compound of a metal species, sulfur, and oxygen. For example, the compound may be a sulfate or an oxy-sulfate. The compound may, in some embodiments, include other elements from Group VIA. The first semiconductor layer has a higher band gap as compared to the second semiconductor layer that may allow more light transmission to reach the absorber layer.

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In some instances, the approximating language may correspond to the precision of an instrument for measuring the value.

In the following specification and the claims, the singular forms “a”, “an” and “the” include plural referents unless the context clearly dictates otherwise.

The terms “first,” “second,” and the like, herein do not denote any order, quantity, or importance, but rather are used to distinguish one element from another.

The terms “transparent region” and “transparent layer” as used herein, refer to a region or a layer that allows an average transmission of at least 80% of incident electromagnetic radiation having a wavelength in a range from about 300 nm to about 850 nm.

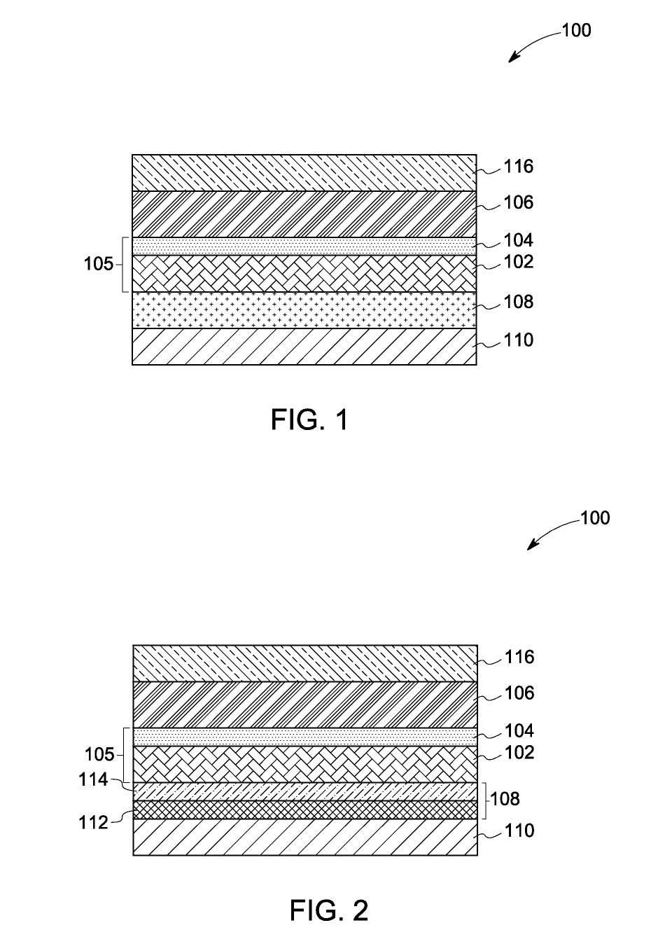

As discussed in detail below, some embodiments of the invention are directed to a photovoltaic device 100 as illustrated in FIGS. 1-2. The photovoltaic device 100 includes a first semiconductor layer 102, a second semiconductor layer 104 disposed on the first semiconductor layer 102, and a third semiconductor layer 106 disposed on the second semiconductor layer 104. The first semiconductor layer 102 includes a compound having a metal species, sulfur, and oxygen. The metal species may include zinc, magnesium, tin, indium, or a combination thereof.

As used herein, the term “disposed on” refers to layers disposed directly in contact with each other or indirectly by having intervening layers there between, unless otherwise specifically indicated.

According to embodiments of the invention, the second semiconductor layer 104 and the third semiconductor layer 106 may form a hetero-junction. As used in this context, a hetero-junction is a semiconductor junction that is composed of layers of dissimilar semiconductor materials. These materials usually have non-equal band gaps. As an example, a hetero-junction can be formed by disposing a layer or region of one conductivity type material on a layer or region of opposite conductivity type material, e.g., a “p-n” junction. The term “conductivity-type material”, as used herein refers to a type of a doped semiconductor material. Those skilled in the art are familiar that a doped semiconductor may be n-type or p-type based on a dopant introduced to the semiconductor.

The second semiconductor layer 104 may form a window layer, according to some embodiments of the invention. A window layer in a PV device is broadly defined as all the layers through which light passes before being absorbed in an absorber layer. The “window layer”, as used herein, refers to substantially transparent single layer or multiple layers that allow light to pass through to an absorber layer, and forms a hetero-junction with the absorber layer.

Non-limiting exemplary materials for the second semiconductor layer 104 include cadmium sulfide (CdS), indium sulfide (In₂S₃), indium selenide (In₂Se₃), zinc sulfide (ZnS), (ZnTe), zinc selenide (ZnSe), cadmium selenide (CdSe), zinc oxihydrate (Zn(OH)), or combinations thereof. In some embodiments, the second semiconductor layer 104 includes an n-type semiconductor material. In a particular embodiment, the second semiconductor layer 104 includes n-type CdS.

Typically, in CdTe thin film PV devices, CdS has been commonly used as a window material. However, one major drawback for CdS is its relatively low band gap (−2.4 eV). Low band gap results in current loss in the device due to the absorption in the short-wavelength region (for example, light with wavelength less than about 512 nm gets absorbed in the CdS layer, resulting in about 10-20% loss of the solar spectrum). A reduced thickness of the CdS layer may desirably reduce the absorption, however the reduced thickness can adversely impact the device performance.

Embodiments of the invention described herein address the noted shortcomings of the state of the art. According to embodiments of the invention, the device 100 includes a first semiconductor layer 102 disposed on the second semiconductor layer 104. In one embodiment, the first semiconductor layer 102 includes a higher band gap material than the second semiconductor layer 104. Incorporation of such a higher band gap material layer may advantageously allow a thinner second semiconductor layer 104 (for example, CdS) and, in turn, more light transmission through a window layer 105.

The first semiconductor layer 102 includes a compound having a metal species, sulfur, and oxygen. A compound, as used herein, refers to a macroscopically homogeneous material (substance) consisting of atoms or ions of two or more different elements in definite proportions, and at definite lattice positions. For example, the metal species, sulfur, and oxygen have defined lattice positions in the crystal structure of the compound, as contrasted, for example to an oxygenated metal sulfide where oxygen may be a dopant that is substitutionally inserted on sulfur sites, and not a part of the compound lattice. Furthermore, as discussed previously, the compound may have a band gap higher than the band gap of the material of the second semiconductor layer 104 (for example, CdS). In one embodiment, the band gap of the compound may be in a range from about 2.4 eV to about 5 eV.

In one embodiment, the compound may include a sulfate, an oxysulfate, or a combination thereof. In certain embodiments, the metal species is zinc. In these instances, the compound may include zinc sulfate, zinc oxysulfate, or a combination thereof.

The amount of the compound in the first semiconductor layer 102 may be high or nearly 100 percent. In some embodiments, the first semiconductor layer 102 may have at least about 30 volume percent of the compound, based on the total volume of the first semiconductor layer. In some instances, the compound is present in an amount between about 30 volume percent to about 90 volume percent. In some instances, the amount of the compound may be between about 40 volume percent and about 70 volume percent, based on the total volume of the first semiconductor layer. Some other phases such as oxides, sulfites, sulfides or oxysulfides also may be present.

The thickness of the window layer is typically desired to be minimized in a photovoltaic device to achieve high efficiency. With the presence of the first semiconductor layer 102, the thickness of the second semiconductor layer 104 (e.g., CdS layer) may be reduced to improve the performance of the present device. Moreover, the present device may achieve a reduction in cost of production because of the use of lower amounts of CdS. In some embodiments, the thickness of the second semiconductor layer 104 ranges from about 5 nanometers to about 100 nanometers. In some embodiments, the thickness of the first semiconductor layer 102 may be between about 20 nanometers and about 200 nanometers.

In one embodiment, the third semiconductor layer 106 is an absorber layer. The term “absorber layer”, as used herein, refers to a semiconductor layer wherein the electromagnetic radiation is absorbed and converted to electron-hole pairs. Typically, when solar radiation is incident on the photovoltaic device, electrons in the absorber layer are excited from a lower energy “ground state,” in which they are bound to specific atoms in the solid, to a higher “excited state,” in which they can move through the solid, as free electrons (charge carriers). The electron-hole pairs generated in the absorber layer are separated by an internal field generated by the respective doped semiconductor layers, so as to create the photovoltaic current. In this manner, the device 100, when exposed to appropriate illumination, generates a photovoltaic current, which is collected by the electrically conductive layers 108 and 116, which are in electrical communication with appropriate layers of the device 100.

The absorber layer 106 may contain a suitable amount of a dopant to increase the efficiency of the device. In some embodiments, the absorber layer 106 includes a p-type semiconductor material. In one embodiment, the absorber layer 106 has an effective carrier density greater than about 1×10¹³ per cubic centimeter. In some embodiments, the absorber layer 106 has an effective carrier density in a range from about 5×10¹⁴ per cubic centimeter to about 1×10²⁰ per cubic centimeter.

The absorber layer 106 may be a single layer or may have multiple layers. The single layer may include a p-type or p+-type semiconductor material. The term “p+-type semiconductor layer” as used herein refers to a semiconductor layer having an excess mobile p-type carrier or hole density compared to the p-type charge carrier or hole density in a semiconductor layer. Multiple layers may have more than one layer, each layer having different material (described below), different type (p-type or p+-type), or different material and type, both. In these instances, multiple layers are arranged according to their increasing effective carrier densities from a layer adjacent to the second semiconductor layer 104 towards a top layer adjacent to a back contact layer 116 (referring to FIGS. 1 and 2). It is desirable that the absorber layer 106 has a heavily doped p-type or p+-type surface adjacent to a back contact layer 116. The p+-type surface of the absorber layer 106 may provide a good interface with a back contact layer 116. Higher carrier densities of the p+-type layer may minimize the series resistance of the back contact layer 116, in comparison to other resistances within the device.

Suitable materials for the third semiconductor layer. that is the absorber layer 106 include, but are not limited to, cadmium telluride (CdTe), zinc telluride (ZnTe), magnesium telluride, manganese telluride, beryllium telluride, mercury telluride, arsenic telluride, antimony telluride, copper telluride, cadmium zinc telluride (CdZnTe), copper indium sulfide (CIS), copper indium gallium selenide (CIGS), copper zinc tin sulfide (CZTS), cadmium magnesium telluride (CdMgTe), and cadmium manganese telluride (CdMnTe), or combinations thereof. Some other suitable materials are amorphous Si:H, amorphous SiC:H, crystalline Si, microcrystalline Si:H, microcrystalline SiGe:H, amorphous SiGe:H, amorphous Ge, microcrystalline Ge, GaAs, BaCuSF, BaCuSeF, BaCuTeF, LaCuOS, LaCuOSe, LaCuOTe, LaSrCuOS, LaCuOSe_{0.6}Te_{0.4}, BiCuOSe, BiCaCuOSe, PrCuOSe, NdCuOS, Sr₂Cu₂ZnO₂S₂, Sr₂CuGaO₃S, (Zn,Co,Ni)₃O₄, and combinations thereof.

In some embodiments, the heavily doped p+-type semiconductor layer includes an additional dopant selected from the group consisting of copper, gold, nitrogen, phosphorus, antimony, arsenic, boron, silver, bismuth, sulfur, sodium, and combinations thereof.

The above-mentioned semiconductor materials may be used alone or in combination. Further, these materials may be present in more than one layer, each layer having different type of semiconductor material or having combinations of the materials in separate layers.

The absorber layer 106 is thicker than the first semiconductor layer 102 and the second semiconductor layer 104. Typically, an absorber layer is sufficiently thick to absorb incident electromagnetic radiation. In some embodiments, the absorber layer 106 has a thickness in the range from about 0.5 micron to about 5 microns. In certain embodiments, the thickness of the absorber layer 106 ranges from about 1.5 microns to about 3 microns.

As discussed previously, the window layer and the absorber layer are typically oppositely doped. In some embodiments, the window layer may be a p-type layer, and the absorber layer may be an n-type layer to form a “p-n” hetero-junction configuration.

In some embodiments, the second semiconductor layer 104, the third semiconductor layer 106 or both layers contain oxygen. Without being bound by any theory, it is believed that oxygen introduction to the second semiconductor layer (for example CdS layer) provides high efficiency and improved device performance. In some embodiments, the amount of oxygen is less than about 20 atomic percent. In some instances, the amount of oxygen is between about 1 atomic percent to about 10 atomic percent. In some instances, for example in the absorber layer, the amount of oxygen is less than about 1 atomic percent. Moreover, the oxygen concentration within the second semiconductor layer 104, the third semiconductor layer 106 or both layers, may be substantially constant or compositionally graded across the thickness of the respective layer.

In some embodiments, as indicated in FIGS. 1-2, the first semiconductor layer 102 is further disposed on a transparent layer 108 that is disposed on a support or substrate 110. In one embodiment, the transparent layer 108 includes an electrically conductive layer (sometimes referred to in the art as a front contact layer) 112 disposed on the substrate 110, as indicated in FIG. 2. In some embodiments, the first semiconductor layer 102 is disposed directly on the electrically conductive layer 112. In an alternate embodiment, the transparent layer 108 includes an electrically conductive layer 112 disposed on the substrate 110 and an additional layer 114 interposed between the electrically conductive layer 112 and the window layer 105, as indicated in FIG. 2. In one embodiment, the transparent layer 108 has a thickness in a range from about 100 nanometers to about 600 nanometers.

In one embodiment, the electrically conductive layer 112 includes a transparent conductive oxide (TCO). Non-limiting examples of transparent conductive oxides include cadmium tin oxide (CTO), indium tin oxide (ITO), fluorine-doped tin oxide (SnO:F or FTO), indium-doped cadmium-oxide, cadmium stannate (Cd₂SnO₄ or CTO), doped zinc oxide (ZnO), such as aluminum-doped zinc-oxide (ZnO:Al or AZO), indium-zinc oxide (IZO), and zinc tin oxide (ZnSnOₓ), (Cd,Zn)₂SnO₄, or combinations thereof. Depending on the specific TCO employed and on its sheet resistance, the thickness of the electrically conductive layer 112 may be in a range of from about 50 nm to about 600 nm, in one embodiment.

The additional layer 114 (optional) is a high resistance transparent (HRT) layer. In one embodiment, the thickness of the HRT layer 114 is in a range from about 10 nm to about 200 nm. Non-limiting examples of suitable materials for the HRT layer 114 include tin dioxide (SnO₂), zinc tin oxide (ZTO), zinc-doped tin oxide (SnO₂:Zn), zinc oxide (ZnO), indium oxide (In₂O₃), zinc stannate (Zn₂SnO₄), or combinations thereof.

In one embodiment, the substrate 110 is transparent over the range of wavelengths for which transmission through the substrate 110 is desired. In one embodiment, the substrate 110 may be transparent to visible light having a wavelength in a range from about 350 nm to about 1200 nm. In some embodiments, the substrate 110 includes a material capable of withstanding heat treatment temperatures greater than about 600° C., such as, for example, silica or borosilicate glass. In some other embodiments, the substrate 110 includes a material that has a softening temperature lower than 600° C., such as, for example, soda-lime glass or a polyimide. In some embodiments certain other layers may be disposed between the transparent layer 108 and the substrate 110, such as, for example, an anti-reflective layer, a down converting layer, or a barrier layer (not shown).

As indicated in FIGS. 1-2, in such embodiments, the electromagnetic radiation enters from the substrate 110, and after passing through the transparent layer 108 and the window layer 105, enters the absorber layer 106, where the conversion of electromagnetic energy of incident light (for instance, sunlight) to electron-hole pairs (that is, to free electrical charge) occurs.

In one embodiment, the photovoltaic device 100 further includes a second electrically conductive layer 116, as indicated in FIGS. 1-2. The second electrically conductive layer 116 may be a metal layer, also called a back contact layer 116. The layer 116 is disposed on the third semiconductor layer 106. In some embodiments, the layer 116 is disposed on a heavily doped p-type material, i.e. a p+-type semiconductor layer of the third semiconductor layer 106. The high carrier density at the interface of the third semiconductor layer 106 and the back contact layer 116 may provide improved electrical contact between the layer 116 and the third semiconductor layer 106. Accordingly, in some embodiments, any suitable metal having the desired conductivity and reflectivity may be selected as the back contact layer 116. Non-limiting examples of the metal for the layer 116 include gold, platinum, molybdenum, tungsten, tantalum, palladium, aluminum, chromium, nickel, or silver. In certain embodiments, another metal layer (not shown), for example, aluminum, may be disposed on the metal layer 116 to assist with lateral conduction to the outside circuit.

In one embodiment, a method of making a photovoltaic device 100, as illustrated in FIGS. 1-2, is provided. The method generally includes disposing the second semiconductor layer 104 between the first semiconductor layer 102 and the third semiconductor layer 106. As understood by a person skilled in the art, the sequence of disposing the three layers or the whole device may depend on a desirable configuration, for example “substrate” or “superstrate” configuration of the device.

A variety of deposition techniques are available for depositing the semiconductor layers discussed above. Suitable techniques may include one or more of close-space sublimation (CSS), vapor transport method (VTM), chemical bath deposition (CBD), sputtering, electrochemical deposition (ECD), ion-assisted physical vapor deposition (IAPVD), radio frequency or pulsed magnetron sputtering (RFS or PMS), metal organic chemical vapor deposition (MOCVD), and plasma enhanced chemical vapor deposition (PECVD). In some particular embodiments, for example in substrate configuration device, suitable techniques for depositing the first semiconductor layer 102 may be capable of directly depositing the crystalline metal sulfates or metal oxysulfates at temperatures lower than about 550 degrees Celsius. Such deposition techniques, for example, include sputtering, and MOCVD.

In some particular embodiments, a method for making a device in superstrate configuration is described. Referring to FIGS. 1-2, the method includes disposing a transparent layer 108 including an electrically conductive layer 112 on a substrate 110 by any suitable technique, such as sputtering, chemical vapor deposition, spin coating, spray coating, or dip coating. Referring to FIG. 2, in some embodiments, an optional HRT layer 114 may be deposited on the electrically conductive layer 112 using sputtering to form the transparent layer 108.

A first semiconductor layer 102 may be then disposed on the transparent layer 108. The step of disposing the first semiconductor layer 102 includes depositing the layer 102 by a suitable deposition technique followed by a thermal processing step. Suitable deposition techniques for the first semiconductor layer 102 include one or more of sputtering, chemical bath deposition (CBD), atomic layer deposition (ALD), spray pyrolysis, metalorganic chemical vapor deposition (MOCVD), close-space sublimation (CSS), vapor transport method (VTM), diffused transport deposition (DTD), and electrochemical deposition (ECD) depending on a target material used for the deposition, and various deposition conditions.

In one embodiment, a sulfate or oxy-sulfate may be directly deposited by a suitable deposition technique, for example MOCVD at lower than about 500 degrees Celsius. In some embodiments, a sulfide of the metal species may be deposited in presence of high amount (more than about 5 volume percent) of oxygen as a process gas (that is, in an oxygen-containing environment) throughout the growth process. In these instances, the suitable deposition technique may be sputtering. In some instances, the deposition of the first semiconductor layer 102 may be performed in the presence of an amount of oxygen between about 5 volume percent to about 40 volume percent. In some instances, the amount of oxygen may be as high as 50 volume percent. In certain instances, the amount of oxygen may be between about 10 volume percent and about 25 volume percent.

The amount of oxygen as described herein refers to the oxygen concentration present during deposition of a semiconductor layer, (for example, the layer 102) or as-deposited layer, that is, before any post-deposition processing. Without being bound by any theory, it is observed that oxygen concentration in the semiconductor layer may change substantially during post-deposition processing (for example, thermal processing, CdCl₂ treatment) depending, in part, on the conditions of processing.

The thermal processing step can take place under any suitable condition. In one embodiment, the thermal processing step, for example, an annealing step may be carried out in an environment comprising an inert gas, oxygen, air, or a combination thereof. The annealing may be carried out under a suitable pressure between about 1 mTorr and about 760 Torr. In certain instances, the annealing pressure may range between about 1 Torr and 500 Torr. The first semiconductor layer may be annealed between about 500 degrees Celsius and about 700 degrees Celsius, and in certain instances, between about 550 degrees Celsius and about 650 degrees Celsius. The annealing may be carried out for a suitable duration, for example, about 10 minutes to about 30 minutes.

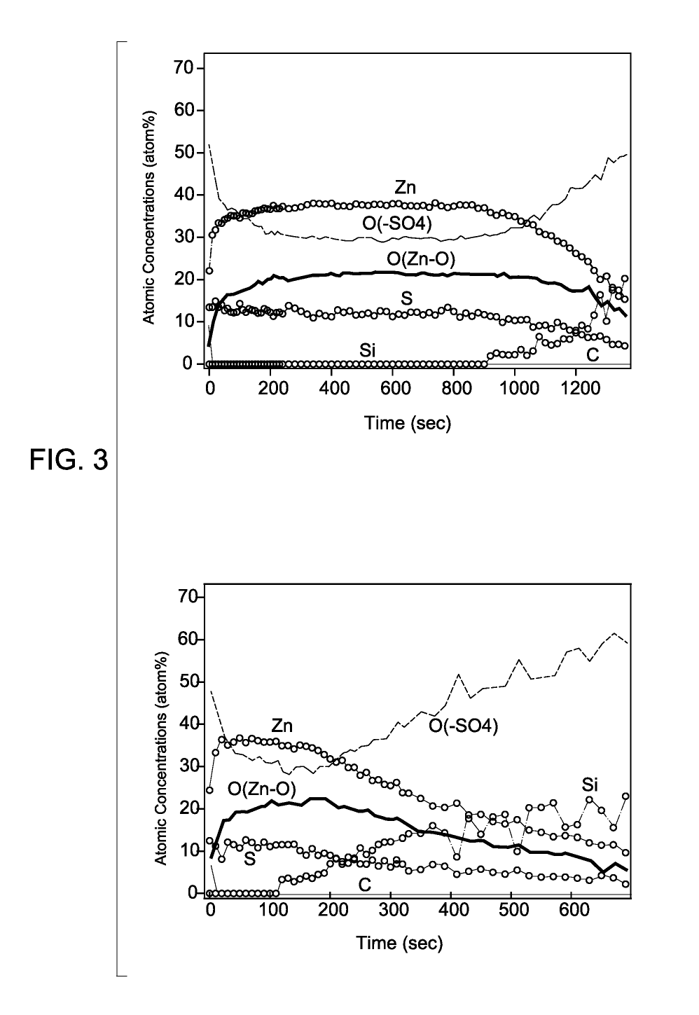

During the annealing step, recrystallization and chemical changes may occur in the first-semiconductor layer 102, and the desired compound (for example, a sulfate and/or oxysulfate) can be formed. While not wishing to be bound by any theory, it was observed that the desired compound, for example a sulfate and/or oxysulfate for the first semiconductor layer were generally obtained upon thermal treatment of the deposited layer. FIG. 3 shows X-ray Photoelectron Spectroscopy (XPS) profiles of a ZnS layer deposited in presence of 10 volume % oxygen, before and after annealing. After annealing, the oxygen content in the final ZnS:O layer is about 50 atomic percent. These XPS graphs clearly suggest presence of oxide and/or sulfate phases after annealing. Furthermore, Grazing Incidence X-ray Diffraction (GIXRD) data indicated formation of zinc oxysulfate (Zn₃O(SO₄)₂) after annealing.

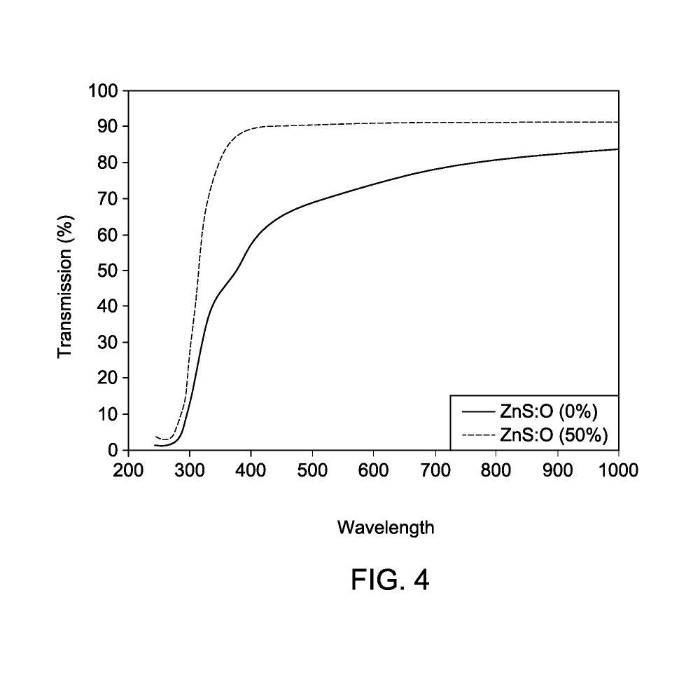

Moreover, FIG. 4 shows optical transmission of ZnS:O layers containing different oxygen levels, for example 0 atomic %, and 50 atomic %. The ZnS:O layer deposited with high oxygen content allow more light transmission as compared to low oxygen containing layer. Quite generally, in the interest of brevity of the discussions herein, a sulfide layer containing an amount of oxygen may be referred to as “ZnS:O layer” with the oxygen amount in the parenthesis.

After thermal processing of the first semiconductor layer 102, the method further includes disposing a second semiconductor layer 104 on the first semiconductor layer 102 followed by disposing the third semiconductor layer 106 on the second semiconductor layer 104. In some embodiments, the second semiconductor layer 104, the third semiconductor layer 106, or both layers may be deposited by sputtering, close-space sublimation (CSS), thermal evaporation, diffused transport deposition (DTD), or vapor transport deposition (VTD). In one embodiment, the thermal processing step may be performed after depositing the second semiconductor layer 104 on the first semiconductor layer 102 before the deposition of the third semiconductor layer 106.

In some embodiments, the two layers (the first and second semiconductor layer 102 and 104) may be deposited using the same deposition process. In some embodiments, the two layers are deposited by close-space sublimation (CSS), diffused transport deposition (DTD), sputtering, or vapor transport deposition (VTD). In particular embodiments, the two layers are deposited by sputtering. In some embodiments, the three layers (the first, second, and third semiconductor layer 102, 104, and 106) may be deposited using the same deposition process.

Incorporation of oxygen in the second semiconductor layer 104, the third semiconductor layer 106, or both may be employed during deposition. In some embodiments, the deposition is carried out in the presence of oxygen. An alternate method uses a source material containing oxygen to deposit a film or layer, in some other embodiments. Typically, particles or atoms are derived from the source material, and are deposited on a substrate or support to form a film. The source material may include an oxidation product of a semiconductor material, according to some embodiments of the invention.

Moreover, CdTe deposition on CdS in the presence of oxygen may be desirable as oxygen at the CdTe/CdS interface may provide improved interface characteristics that may result in higher device efficiencies and enhanced device stability. Without being bound by any theory, it is believed that oxygen at the interface between the second semiconductor layer 104, and the third semiconductor layer 106 (for example, CdS/CdTe) provides improved interface properties (for example, reduce the lattice mismatch, lower pinhole density, or enhanced alloying among layer constituent elements), allowing for high minority carrier lifetimes at the interface in contact with the window layer.

In one embodiment, after the step of disposing the absorber layer 106, cadmium chloride (CdCl₂) treatment is carried out. A solution of CdCl₂ or CdCl₂ vapor may be used for the treatment. The treatment with CdCl₂ is known to increase the carrier lifetime of the absorber layer 106. The treatment with cadmium chloride may be followed by an etching or rinsing step. In one embodiment, etching may be carried out using a suitable acid. In other embodiments, the CdCl₂ may be rinsed off the surface, resulting in a stoichiometric cadmium telluride at the surface, mainly removing the cadmium oxide and CdCl₂ residue from the surface, leaving a cadmium-to-tellurium ratio of about 1 at the surface. The etching works by removing non-stoichiometric material that forms at the surface during processing. Other etching techniques known in the art that may result in a stoichiometric cadmium telluride at the back interface may also be employed.

In some embodiments, a p+-type semiconductor layer or a p+-type surface may be disposed by chemically treating the absorber layer 106 to increase the carrier density on the back-side (side in contact with the metal layer and opposite to the window layer) of the layer 106. In one embodiment, the photovoltaic device 100 may be completed by depositing a back contact layer, for example, a metal layer 116 on the third semiconductor layer (absorber layer) 106.

In some embodiments, other components (not shown) may be included in the photovoltaic device 100, such as, buss bars, external wiring, laser etches, etc. For example, when the device 100 forms a photovoltaic cell of the photovoltaic module, a plurality of photovoltaic cells may be connected in series, in parallel or both in order to achieve a desired voltage, such as through an electrical wiring connection. Each end of the connected cells may be attached to a suitable conductor such as a wire or bus bar, to direct the generated current to convenient locations for connection to a device or other system using the generated current. In some embodiments, a laser may be used to scribe the deposited layers of the photovoltaic device 100 to divide the device into a plurality of connected cells.

In some embodiments, a manufacturing method may include thermally processing multiple devices (for example, annealing of a compound-containing layer as discussed previously) in a face-to-face arrangement. The method may include thermally processing a first semiconductor assembly comprising a first semiconductor layer (for example, the ZnS:O-containing layer) disposed on a first substrate and thermally processing a second semiconductor assembly comprising another first semiconductor layer disposed on a second substrate. In one embodiment, the two assemblies are thermally processed simultaneously. The first and second semiconductor assemblies are arranged such that the first semiconductor layers face each other with a gap between them during the thermal processing. In some other embodiments, the assemblies may be thermally processed one by one in stand-alone configuration.

In some instances, the manufacturing method further includes disposing at least one spacer between the first semiconductor layers, such that the layers are spaced apart from one another during the thermal processing. Generally speaking, any suitable spacer having the required structural characteristics capable of withstanding the thermal processing conditions (as described previously) may be used for separating the first assembly and the second assembly, and for maintaining a desired gap between the two assemblies.

### EXAMPLES

The examples that follow are merely illustrative, and should not be construed to be any sort of limitation on the scope of the claimed invention.

### Example: Cadmium Telluride Photovoltaic Devices having a Window Layer including a Bi-Layer Structure

A cadmium telluride photovoltaic device was made by depositing several layers on a cadmium tin oxide (CTO) transparent conductive oxide (TCO)-coated substrate. The substrate was a 1.3 millimeters thick CIPV065 glass, which was coated with a CTO transparent conductive layer and a thin high resistance transparent zinc tin oxide (ZTO) buffer layer. The window layer was deposited on the ZTO layer using the following conditions to form three different samples:

Inventive Sample: bi-layer window layer (40 nm first layer+40 nm second layer);

A 40 nm first layer (“layer 1”) of inventive sample was first deposited on the ZTO layer. The layer 1 was deposited by RF sputtering ZnS in the presence of about 10 volume % oxygen atmosphere followed by thermal annealing before depositing a 40 nm second layer (“layer 2”). Annealing was performed in a face-to-face geometry in N₂ atmosphere under about 400 Torr at about 630 degrees Celsius for about 15 minutes. FIG. 3 shows X-ray Photoelectron Spectroscopy (XPS) profiles of the layer 1 before and after annealing. XPS profiles clearly indicate presence of zinc oxysulfate. The layer 2 was then deposited on the layer 1 by DC pulsed sputtering CdS in the presence of about 5 volume % oxygen at room temperature. The layer 2 was not subjected to the annealing treatment.

### Comparative Sample: Single Layer (80 nm CdS Layer)

80 nm single layer was deposited on the ZTO layer by DC pulsed sputtering CdS in 5 volume % oxygen atmosphere.

Following the deposition of the window layer having one of the two mentioned structures, a CdTe layer (about 3 micrometers thick) was deposited over the window layer using a close spaced sublimation process at a substrate temperature of about 550 degrees Celsius in an environment containing 1 Torr of Oxygen and 15 Torr of Helium. The resulting assembly was treated with cadmium chloride in solution and annealed at a temperature of about 370 degrees Celsius for about 40 minutes in air. At the end of the stipulated time, the CdCl₂ was rinsed off and the assembly was treated with a copper solution and subjected to annealing at a temperature of about 200 degrees Celsius for a duration of about 18 minutes. Gold was then deposited on the copper treated layer as the back contact by evaporation process.

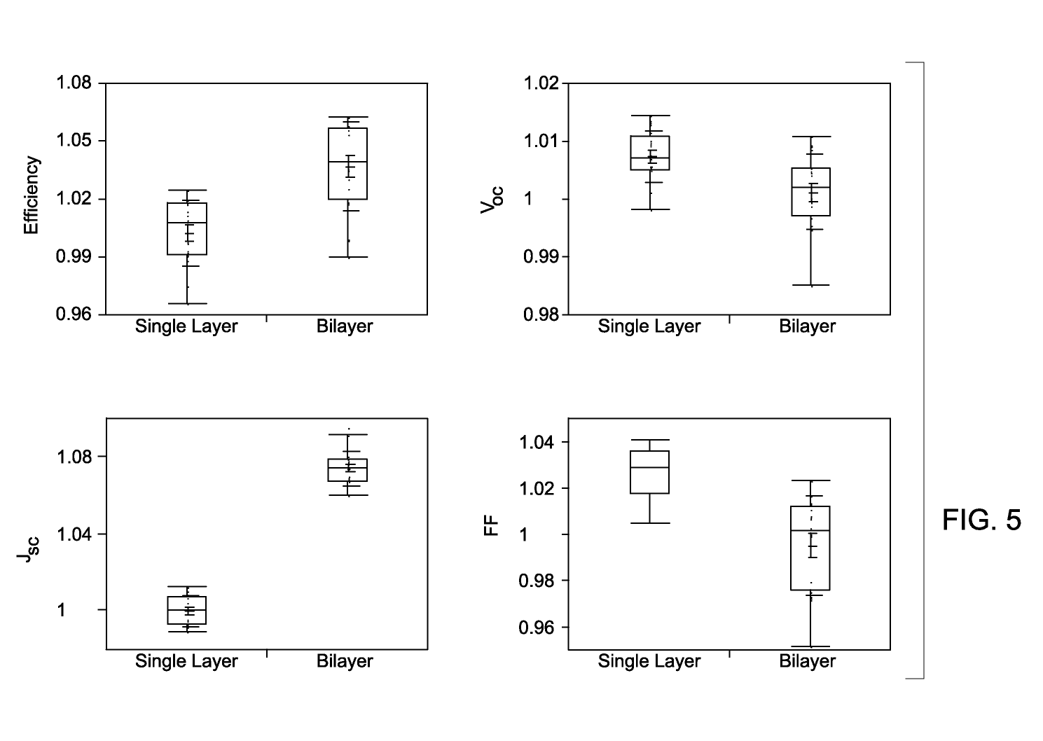

As illustrated in FIG. 5, the device performance parameters showed improvement for the bi-layer {ZnS:O(50%)/CdS:O(5%)} structure when compared to the single-layer structure.

The appended claims are intended to claim the invention as broadly as it has been conceived and the examples herein presented are illustrative of selected embodiments from a manifold of all possible embodiments. Accordingly, it is the Applicants' intention that the appended claims are not to be limited by the choice of examples utilized to illustrate features of the present invention. As used in the claims, the word “comprises” and its grammatical variants logically also subtend and include phrases of varying and differing extent such as for example, but not limited thereto, “consisting essentially of” and “consisting of.” Where necessary, ranges have been supplied; those ranges are inclusive of all sub-ranges there between. It is to be expected that variations in these ranges will suggest themselves to a practitioner having ordinary skill in the art and where not already dedicated to the public, those variations should where possible be construed to be covered by the appended claims. It is also anticipated that advances in science and technology will make equivalents and substitutions possible that are not now contemplated by reason of the imprecision of language and these variations should also be construed where possible to be covered by the appended claims.

1. A photovoltaic device, comprising:
a first semiconductor layer comprising a compound comprising magnesium, sulfur, and oxygen;
a second semiconductor layer disposed on the first semiconductor layer, wherein the second semiconductor layer comprises cadmium sulfide, zinc sulfide, cadmium zinc sulfide, cadmium selenide, indium selenide, indium sulfide, or a combination thereof; and
a third semiconductor layer disposed on the second semiconductor layer, wherein the third semiconductor layer comprises a semiconductor material selected from the group consisting of cadmium telluride, cadmium zinc telluride, cadmium sulfur telluride, cadmium manganese telluride, cadmium magnesium telluride, copper indium gallium selenide (CIGS), copper zinc tin sulfide (CZTS), and combinations thereof.

2. The photovoltaic device of claim 1, wherein the compound is present in an amount at least about 30 volume percent, based on the total volume of the first semiconductor layer.

3. (canceled)

4. The photovoltaic device of claim 1, wherein the compound has a band gap in a range from about 2.4 eV to about 5 eV.

5. The photovoltaic device of claim 1, wherein the compound comprises a sulfate, an oxysulfate, or a combination thereof.

6. (canceled)

7. The photovoltaic device of claim 1, wherein the first semiconductor layer has a thickness in a range from about 20 nanometers to about 200 nanometers.

8. (canceled)

9. The photovoltaic device of claim 1, wherein the second semiconductor layer has a thickness in a range from about 5 nanometers to about 100 nanometers.

10-11. (canceled)

12. The photovoltaic device of claim 1, wherein the third semiconductor layer has a thickness in a range from about 500 nanometers to about 5000 nanometers.

13. The photovoltaic device of claim 1, further comprising a first electrically conductive layer disposed on the first semiconductor layer.

14. The photovoltaic device of claim 13, wherein the first electrically conductive layer comprises cadmium tin oxide, indium tin oxide, zinc tin oxide, fluorine-doped tin oxide, indium-doped cadmium oxide, aluminum-doped zinc oxide, indium zinc oxide, or combinations thereof.

15. The photovoltaic device of claim 10, wherein a second electrically conductive layer is disposed on the third semiconductor layer.

16. The photovoltaic device of claim 15, wherein the second electrically conductive layer comprises gold, platinum, molybdenum, aluminum, chromium, nickel, titanium, tungsten, palladium, tantalum, vanadium, copper or graphite.

17. The photovoltaic device of claim 10, wherein the second semiconductor layer, the third semiconductor layer, or both layers further comprise oxygen.

18. The photovoltaic device of claim 17, wherein the amount of oxygen in the second semiconductor layer, the third semiconductor layer, or both layers is less than about 20 atomic percent.

19. A photovoltaic module comprising a plurality of photovoltaic devices as defined in claim 1.

20. A photovoltaic device, comprising:
a first semiconductor layer comprising a compound comprising magnesium, sulfur, and oxygen disposed on a substrate,
a second semiconductor layer comprising cadmium sulfide disposed on the first semiconductor layer, and
a third semiconductor layer comprising cadmium telluride disposed on the second semiconductor layer.

21-28. (canceled)
